(19) United States
(12) Patent Application Publication
(10) Pub. No.: US 2026/0101565 A1
(43) Pub. Date: Apr. 9, 2026

(54) Transistor and manufacturing method thereof

(71) Applicant: UNITED MICROELECTRONICS CORP., Hsin-Chu City (TW)

(72) Inventors: Ming-Hua Tsai, Tainan City (TW); Wei-Hsuan Chang, Tainan City (TW); Hao-Ping Yan, Tainan City (TW); Chin-Chia Kuo, Tainan City (TW)

(73) Assignee: UNITED MICROELECTRONICS CORP., Hsin-Chu City (TW)

(21) Appl. No.: 18/931,090

(22) Filed: Oct. 30, 2024

(30) Foreign Application Priority Data
Oct. 8, 2024 (TW) 113138270

(51) Int. Cl. H01L 29/51; H01L 29/66; H01L 29/78

(52) U.S. Cl. CPC H10D 64/683; H10D 30/0212; H10D 30/0293; H10D 30/65

(57) ABSTRACT

The invention provides a transistor. The transistor includes a well region arranged in a substrate, a gate structure arranged on the well region, a gate oxide layer, wherein a first portion of the gate oxide layer is thicker than a second portion of the gate oxide layer, a first doped region and a second doped region arranged in the well region, wherein along the horizontal direction, the distance between the first doped region and the first portion of the gate oxide layer is greater than the distance between the second doped region and the second portion of the gate oxide layer, and a salicide block located on the substrate and at one side of the gate structure, wherein the salicide block is located between the first portion of the gate oxide layer and the first doped region.

### BACKGROUND OF THE INVENTION

### 1. Field of the Invention

The present invention relates to a transistor and its manufacturing method, in particular to a transistor including gate oxide layers with different thicknesses, which has the advantage of high stability under high operating voltage.

### 2. Description of the Prior Art

Double-diffused MOS (DMOS) transistor devices have drawn much attention in power devices having high voltage capability. The conventional DMOS transistor devices are categorized into vertical double-diffused MOS (VDMOS) transistor device and lateral double-diffused MOS (LDMOS) transistor device. Having advantage of higher operational bandwidth, higher operational efficiency, and convenience to be integrated with other integrated circuit due to its planar structure, LDMOS transistor devices are prevalently used in high operation voltage environment such as CPU power supply, power management system, AC/DC converter, high-power or high frequency band power amplifier, and level shifting circuit.

### SUMMARY OF THE INVENTION

The invention provides a transistor, which comprises a well region disposed in a substrate, a gate structure disposed above the well region, a gate oxide layer disposed between the gate structure and the well region, wherein a first portion of the gate oxide layer is thicker than a second portion of the gate oxide layer, a first doped region and a second doped region arranged in the well region, wherein the first doped region and the second doped region are located at two opposite sides of the gate structure in a horizontal direction, wherein the distance between the first doped region and the first portion of the gate oxide layer is greater than the distance between the second doped region and the second portion of the gate oxide layer along the horizontal direction, and a conductivity type of the first doped region is the same as a conductivity type of the second doped region, and a salicide block located on the substrate and at one side of the gate structure, wherein the salicide block is located between the first portion of the gate oxide layer and the first doped region.

The invention also provides a method for manufacturing a transistor, which comprises providing a well region disposed in a substrate, forming a gate structure disposed above the well region, forming a gate oxide layer disposed between the gate structure and the well region, wherein a first portion of the gate oxide layer is thicker than a second portion of the gate oxide layer, forming a first doped region and a second doped region arranged in the well region, wherein the first doped region and the second doped region are located at two opposite sides of the gate structure in a horizontal direction, wherein the distance between the first doped region and the first portion of the gate oxide layer is greater than the distance between the second doped region and the second portion of the gate oxide layer along the horizontal direction, and a conductivity type of the first doped region is the same as a conductivity type of the second doped region, and forming a salicide block located on the substrate and at one side of the gate structure, wherein the salicide block is located between the first portion of the gate oxide layer and the first doped region.

The invention is characterized by providing a structure of a high-voltage transistor and a manufacturing method thereof. The threshold voltage of high-voltage transistor is reduced by using gate oxide layers with different thickness portions, and the gate structure can still be applied with high voltage by controlling the thickness ratio between different portions of the gate oxide layer to meet the operating requirements of specific circuits. In addition, by forming a salicide block and extending the salicide block to the drain side of the high-voltage transistor, the doped region on the drain side of the high-voltage transistor is far away from the gate structure for a certain distance, so that the stability of the high-voltage transistor can be improved. And because only the doped region on the drain side is far away from the gate structure, the doped region on the source side is still relatively close to the gate structure, the influence on the Vt (threshold voltage) of the whole high-voltage transistor is small. When the high-voltage transistor is used in the level-up shifting circuit, the condition that the high-voltage transistor cannot be driven when the driving voltage drops may be improved, and the operation performance of the level-up shifting circuit may be improved accordingly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1-2 are schematic drawings illustrating a high-voltage transistor according to a first embodiment of the present invention.

FIG. 3 is a top view schematic drawing illustrating a high-voltage transistor according to an embodiment of the present invention.

FIG. 4 is a schematic drawing illustrating a high-voltage transistor according to a second embodiment of the present invention.

FIG. 5 is a schematic drawing illustrating a high-voltage transistor according to a third embodiment of the present invention.

FIG. 6 is a schematic drawing illustrating a high-voltage transistor according to a fourth embodiment of the present invention.

FIG. 7 is a schematic drawing illustrating a high-voltage transistor according to a fifth embodiment of the present invention.

FIG. 8 is a schematic drawing illustrating a semiconductor device according to an embodiment of the present invention.

FIG. 9 is a schematic equivalent circuit diagram of a level-up shifting circuit according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

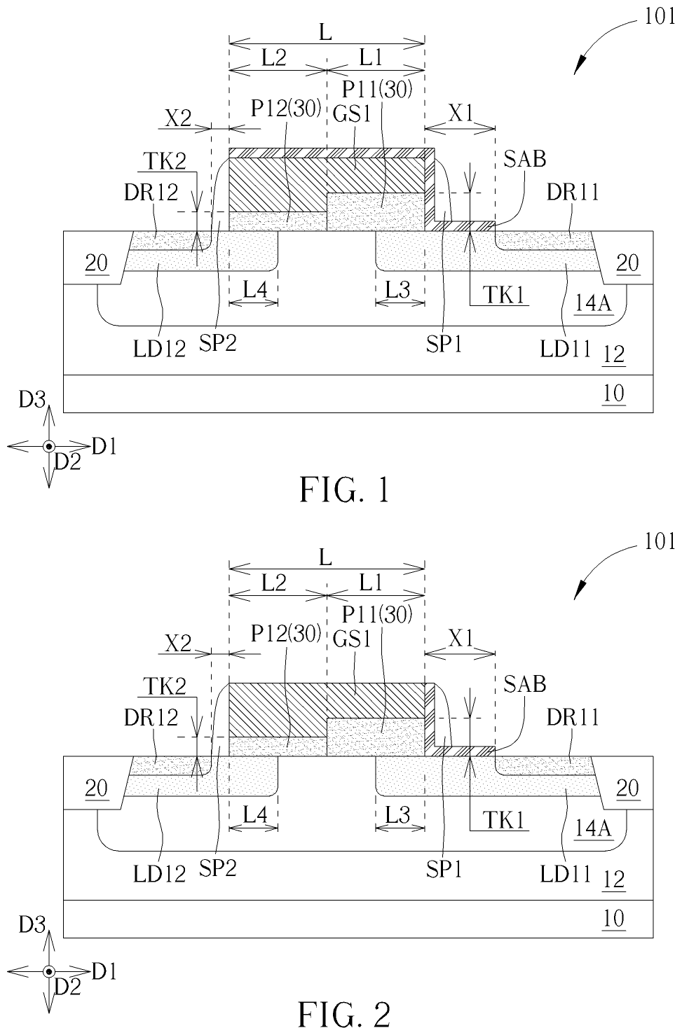

Please refer to FIG. 1. FIG. 1 is a schematic drawing illustrating a high-voltage transistor 101 according to a first embodiment of the present invention. As shown in FIG. 1, the high-voltage transistor 101 includes a well region 14A, a gate structure GS1, a gate oxide layer 30, a first drift region (such as a drift region LD11), and a second drift region (such as a drift region LD12). The well region 14A is disposed in a semiconductor substrate 10, the gate structure GS1 is disposed above the well region 14A, and the gate oxide layer 30 is disposed between the gate structure GS1 and the well region 14A in a vertical direction D3. A first portion P11 of the gate oxide layer 30 is thicker than a second portion P12 of the gate oxide layer 30, and a thickness TK2 of the second portion P12 is greater than or equal to one eighth of a thickness TK1 of the first portion P11. The drift region LD11 and the drift region LD12 are disposed in the well region 14A, and at least a part of the drift region LD11 and at least a part of the drift region LD12 are located at two opposite sides of the gate structure GS1 in a horizontal direction D1, respectively. A conductivity type of the drift region LD11 is identical to a conductivity type of the drift region LD12. In this embodiment, the relatively thin second portion P12 of the gate oxide layer 30 may be used to lower a threshold voltage of the high-voltage transistor 101, and the thickness ratio relationship between the first portion P11 and the second portion P12 of the gate oxide layer 30 may be controlled for avoiding the second portion P12 being too thin. Therefore, high voltage may still be applied to the gate structure GS1 for satisfying operation requirements of specific circuits (such as level shifting circuits, but not limited to this), and the operation performance of the high-voltage transistor 101 and/or related circuits including the high-voltage transistor 101 may be improved accordingly.

In some embodiments, the high-voltage transistor 101 may further include a deep well region 12, an isolation structure 20, a first doped region (such as a doped region DR11), a second doped region (such as a doped region DR12). The semiconductor substrate 10 may include a silicon substrate, an epitaxial silicon substrate, a silicon germanium substrate, a silicon carbide substrate, a silicon-on-insulator (SOI) substrate, or a substrate made of other suitable semiconductor materials. The isolation structure 20 may include a single layer or multiple layers of insulating materials such as oxide insulating materials (e.g., silicon oxide) or other suitable insulating materials. The deep well region 12 may be disposed in the semiconductor substrate 10 and located under the well region 14A in the vertical direction D3, and at least a part of the isolation structure 20 may be disposed in the semiconductor substrate 10 for defining a region located corresponding to the high-voltage transistor in the semiconductor substrate 10. The doped region DR11 may be disposed in the drift region LD11, the doped region DR12 may be disposed in the drift region LD12, and the doped region DR11 and the doped region DR12 may be located at two opposite sides of the gate structure GS1 in the horizontal direction D1, respectively. In some embodiments, the doped region DR11 and the doped region DR12 may be source/drain doped regions in the high-voltage transistor 101, therefore, the doped region DR11 can be regarded as a part of the drain electrode, and the doped region DR12 can be regarded as a part of the source electrode. In some embodiments, the deep well region 12, the well region 14A, the drift region LD11, the drift region LD12, the doped region DR11, and the doped region DR12 may be doped regions formed by performing doping processes (such as implantation processes) to the semiconductor substrate 10. A conductivity type of the doped region DR11 and a conductivity type of the doped region DR12 may be identical to the conductivity type of the drift region LD11 and the conductivity type of the drift region LD12, and the dopant concentration in the doped region DR11 and the doped region DR12 may be higher than the dopant concentration in the drift region LD11 and the drift region LD12. In some embodiments, the drift region LD11 and the drift region LD12 may be formed concurrently by the same process and include substantially the same dopant and/or have substantially the same dopant concentration, and the doped region DR11 and the doped region DR12 may be formed concurrently by the same process and include substantially the same dopant and/or have substantially the same dopant concentration. In addition, the conductivity type of the well region 14A may be complementary to the conductivity type of the doped region DR11, the doped region DR12, the drift region LD11, and the drift region LD12, and the conductivity type of the deep well region 12 may be complementary to or identical to the conductivity type of the well region 14A according to the type of the high-voltage transistor 101. Therefore, the conductivity type of the deep well region 12 may be identical to or complementary to the conductivity type of the doped region DR11, the doped region DR12, the drift region LD11, and the drift region LD12.

For example, when the deep well region 12 is a deep n-type well region and the high-voltage transistor 101 is an n-type transistor, the well region 14A may be a p-type well region, the drift region LD11 and the drift region LD12 may be n-type doped drift regions, and the doped region DR11 and the doped region DR12 may be n-type heavily doped regions. In addition, when the deep well region 12 is a deep n-type well region and the high-voltage transistor 101 is a p-type transistor, the well region 14A may be an n-type well region, the drift region LD11 and the drift region LD12 may be p-type doped drift regions, and the doped region DR11 and the doped region DR12 may be p-type heavily doped regions. In some embodiments, n-type dopants for forming the n-type doped region may include phosphorus (P), arsenic (As), or other suitable n-type doping materials, and p-type dopants for forming the p-type doped region may include boron (B), gallium (Ga), or other suitable p-type doping materials. In addition, a part of the drift region LD11 and a part of the drift region LD12 may be disposed under the gate structure GS1 and the gate oxide layer 30 in the vertical direction D3, but not limited thereto. In some embodiments, the drift region LD11 disposed under the gate structure GS1 and the gate oxide layer 30 in the vertical direction D3 may have a length L3 in the horizontal direction D1, which may be less than or equal to a length L1 of the first portion P11 of the gate oxide layer 30 in the horizontal direction D1, and the drift region LD12 disposed under the gate structure GS1 and the gate oxide layer 30 in the vertical direction D3 may have a length L4 in the horizontal direction D1, which may be less than or equal to a length L2 of the second portion P12 of the gate oxide layer 30 in the horizontal direction D1, but not limited thereto.

The gate oxide layer 30 may include silicon oxide or other suitable oxide materials. In some embodiments, a bottom surface of the first portion P11 of the gate oxide layer 30 and a bottom surface of the second portion P12 of the gate oxide layer 30 may be substantially coplanar, a top surface of the first portion P11 may be higher than a top surface of the second portion P12 in the vertical direction D3, and the first portion P11 may be directly connected with the second portion P12, but not limited thereto. In addition, the relatively thin second portion P12 in the gate oxide layer 30 may be used to lower the threshold voltage, but the second portion P12 cannot be too thin so as to avoid the influence on the ability of the high-voltage transistor 101 to handle high voltage. The ratio of the thickness TK2 of the second portion P12 to the thickness TK1 of the first portion P11 can be maintained in a certain range according to the design requirements, for example, the ratio of the thickness TK2 to the thickness TK1 is more than ⅛, but it is not limited to this. In some embodiments, the thickness TK1 and the thickness TK2 may be between 50 nm and 400 nm, but not limited thereto. In addition, the length L1 of the first portion P11 in the horizontal direction D1 and the length L2 of the second portion P12 in the horizontal direction D1 may be substantially equal or different, and the present invention is not limited to this. In addition, the sum of the length L1 and the length L2 is defined as the length L, which is the total length of the gate oxide layer 30.

Except for the characteristics that the above gate oxide layer 30 has different thicknesses, in this embodiment, a salicide block SAB is covered on the top surface of the gate structure GS1, and the salicide block SAB extends to the surface of the substrate near the doped region DR11 and the sidewall of the gate structure GS1. The salicide block SAB is, for example, silicon nitride or silicon oxynitride, but is not limited thereto. In addition, in this embodiment, the spacer SP1 and the spacer SP2 are located at two sides of the gate structure GS1, respectively, and the spacer SP1 and the spacer SP2 may comprise a single layer or multiple layers of dielectric materials, such as silicon oxide, silicon nitride, silicon oxynitride or other suitable dielectric materials. In the following steps, the doped region DR11 and the doped region DR12 are respectively connected to the drain terminal and the source terminal of the high-voltage transistor. For convenience of explanation, the side of the gate structure GS1 near the doped region DR11 is defined as the drain side, and the side of the gate structure GS1 near the doped region DR12 is defined as the source side. The spacer SP1 is located on the drain side of the gate structure GS1 and above the salicide block SAB, while the spacer SP2 is located on the source side of the gate structure GS1 and directly contacts the sidewall of the gate structure GS1. In the actual process, the gate structure GS1, the salicide block SAB and the spacers SP1 and SP2 are formed first, and then the doped regions DR11 and DR12 are formed in the substrate 10 by ion doping and other steps. Because part of the substrate 10 is blocked by the salicide block SAB and the spacers SP1 and SP2, the doped regions DR11 and DR12 will be formed in the substrate 10 not covered by the salicide block SAB and the spacers SP1 and SP2. In other words, after the doping step is completed, the doped region DR11 will be disposed adjacent to the salicide block SAB, and the doped region DR12 will be disposed adjacent to the spacer SP2.

It is worth noting that in this embodiment, because the salicide block SAB only covers the drain side of the gate structure GS1 (i.e., the side close to the doped region DR11) and does not cover the substrate surface on the source side (i.e., the side close to the doped region DR12), the distance between the doped region DR11 and the first portion P11 of the gate structure GS1 in the horizontal direction D1 will be greater than the distance between the doped region DR12 and the second portion P12 of the gate structure GS1. Specifically, as shown in FIG. 1, the distance between the doped region DR11 and the first portion P11 of the gate structure GS1 is defined as X1, and the distance between the doped region DR12 and the second portion P12 of the gate structure GS1 is defined as X2, where X1>X2.

In addition, the gate structure GS1 can be a polysilicon gate or a metal gate. If the gate structure GS1 is a polysilicon gate, a contact structure (not shown) can be formed in the subsequent step to penetrate the salicide block SAB located on the top surface of the gate structure GS1, so that the contact structure can be electrically connected with the gate structure GS1. On the other hand, if the gate structure GS1 is a metal gate, a metal gate replacement (RMG) process is needed to replacement the gate structure GS1 shown here with a metal gate. In this embodiment, the salicide block SAB located on the top surface of the gate structure GS1 needs to be removed to facilitate the RMG process. As shown in FIG. 2, it shows a schematic cross-sectional view of the high-voltage semiconductor structure after the salicide block SAB on the top surface of the gate structure GS1 is removed. In this embodiment, the salicide block SAB on the top surface of the gate structure GS1 has been removed, but the salicide block SAB may cover the sidewall on the drain side of the gate structure GS1 and some adjacent substrate surfaces. Preferably, the gate structure GS1 in FIG. 1 may be a sacrificial gate structure or a polysilicon gate, while the gate structure GS1 in FIG. 2 is a metal gate, but the present invention is not limited to this, and the gate structure GS1 in FIG. 2 may also be a polysilicon gate.

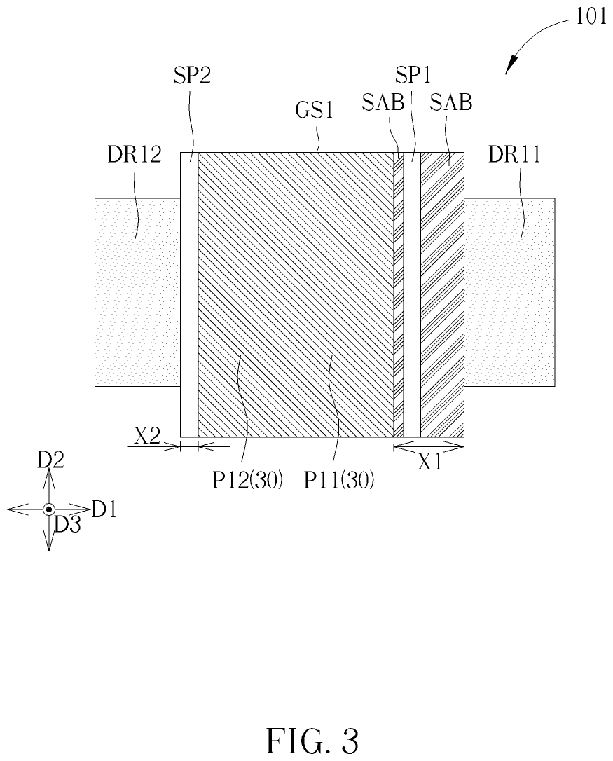

Reference can be made to FIG. 2 and FIG. 3 together, and FIG. 3 is a schematic plan view of a high-voltage transistor according to an embodiment of the present invention. Seen from the plane formed by the horizontal direction D1 and the horizontal direction D2, the salicide block SAB covers part of the surface of the substrate 10 near the drain side of the high-voltage transistor, so that the doped region DR11 on the drain side is far away from the gate structure GS1, but the doped region DR12 on the source side is still relatively close to the gate structure GS1. According to the experimental results of the applicant, because the operating voltage of the high-voltage transistor is relatively large (usually more than 10 volts, but not limited to this), the drain terminal connected to the high-voltage source (i.e., the doped region DR11) generates a relatively large electric field, which easily leads to defects such as voltage collapse or tunneling effect, and affects the performance of the high-voltage transistor. Therefore, in the concept of the present invention, by setting the salicide block SAB and extending the salicide block SAB to the drain side of the gate structure GS1, the doped region DR11 is located far away from the gate structure GS1, wherein the substrate 10 between the doped region DR11 and the gate structure GS1 can be regarded as a resistor connected in series between the doped region DR11 and the gate structure GS1. Therefore, when a high voltage passes through the doped region DR11, it is less likely for the high voltage to penetrate through the gate oxide layer 30 to affect the performance of the high-voltage transistor, thereby improving the stability of the high-voltage transistor.

On the other hand, the present invention does not extend the salicide block SAB to the source side (i.e., the side close to the doped region DR12), because the applicant's experimental results show that if the salicide block SAB is extended to the source side and the doped region DR12 is far away from the gate structure GS1, the threshold voltage (Vt) of the high-voltage transistor will be obviously increased, which means that more voltage is needed to drive the high-voltage transistor. On the contrary, if only the salicide block SAB is extended to the drain side, the influence on the threshold voltage (Vt) is almost negligible. With the progress of semiconductor manufacturing process, the volume and driving voltage of semiconductor devices are getting smaller and smaller, and increasing the threshold voltage of high-voltage transistors will be detrimental to the performance of high-voltage transistors. Therefore, in various embodiments of the present invention, the salicide block SAB is only extended to the drain side and not to the source side.

The following description will detail the different embodiments of the present invention. To simplify the description, the following description will detail the dissimilarities among the different embodiments and the identical features will not be redundantly described. In order to compare the differences between the embodiments easily, the identical components in each of the following embodiments are marked with identical symbols.

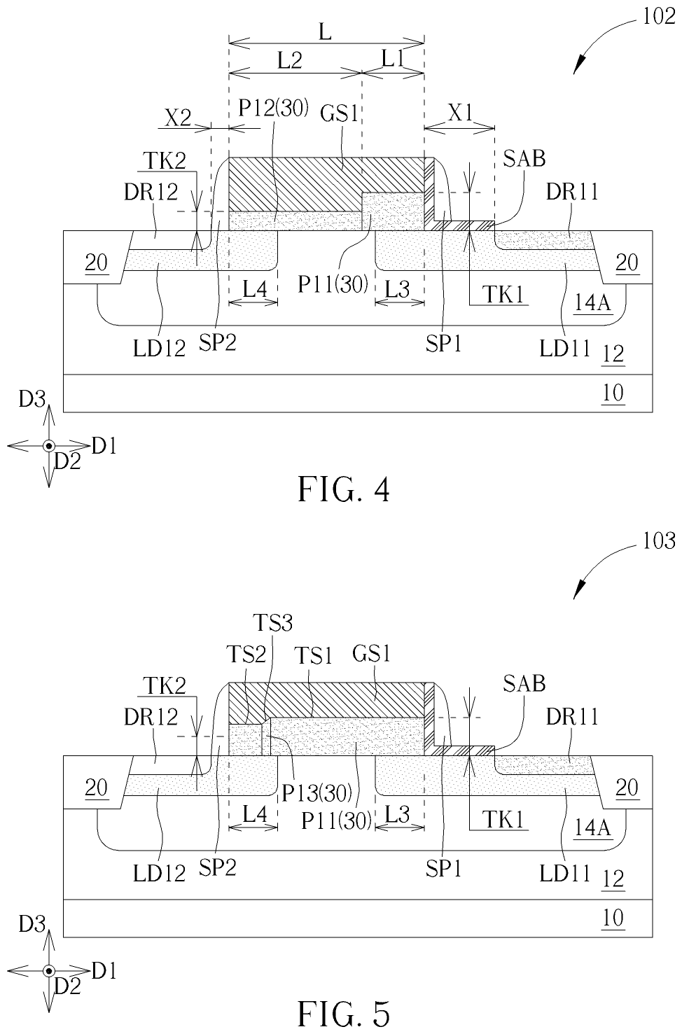

Please refer to FIG. 4, which is a schematic diagram of a high-voltage transistor 102 according to a second embodiment of the present invention. In this embodiment, the lengths L1 and L2 of the first portion P11 and the second portion P12 of the gate oxide layer 30 in the horizontal direction D1, or the lengths L3 and L4 of the drift region LD11 and the drift region LD12 in the horizontal direction D1 can be adjusted according to requirements, and all the above changes are within the scope of the present invention. For example, as shown in FIG. 4, in the high-voltage transistor 102, the length L1 of the first portion P11 of the gate oxide layer 30 in the horizontal direction D1 is smaller than the length L2 of the second portion P12 of the gate oxide layer 30 in the horizontal direction D1. It can be understood that only one possible variation is depicted in FIG. 4, and even other variations (for example, the length L1 of the first portion P11 of the gate oxide layer 30 is greater than the length L2 of the second portion P12, etc.) are not depicted, but are also within the scope of the present invention.

Please refer to FIG. 5. FIG. 5 is a schematic drawing illustrating a high-voltage transistor 103 according to a third embodiment of the present invention. As shown in FIG. 5, in the high-voltage transistor 103, the gate oxide layer 30 may further include a third portion P13 disposed between the first portion P11 and the second portion P12, and a top surface TS3 of the third portion P13 may be a sloping surface connected with a top surface TS1 of the first portion P11 and a top surface TS2 of the second portion P12, respectively, and the negative influence of excessive surface undulation of the gate oxide layer 30 on the gate structure GS1 may be improved accordingly. In addition, the third portion P13 in this embodiment may also be applied to other embodiments of the present invention according to some design considerations.

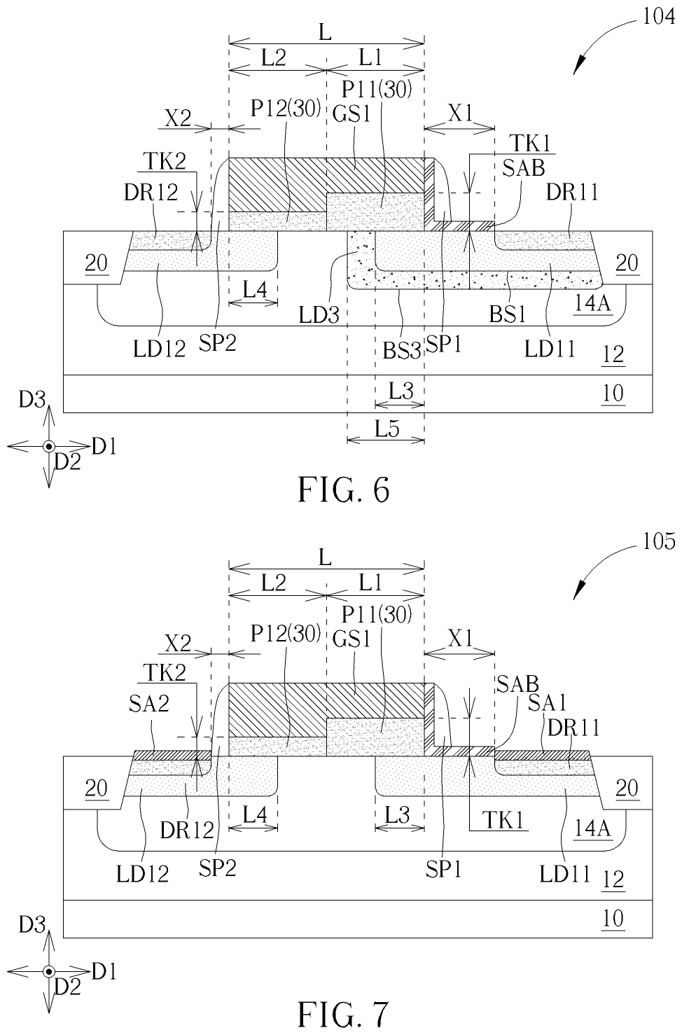

Please refer to FIG. 6. FIG. 6 is a schematic drawing illustrating a high-voltage transistor 104 according to a fourth embodiment of the present invention. As shown in FIG. 6, the high-voltage transistor 104 may further include a third drift region (such as a drift region LD3) disposed in the well region 14A and located under the drift region LD11. The drift region LD3 may be used to adjust the range of the drift region located corresponding to the doped region DR11, especially when the drift region LD11 and the drift region LD12 are formed concurrently by the same process, but not limited thereto. Therefore, a conductivity type of the drift region LD3 is identical to the conductivity type of the drift region LD11, and a dopant concentration in the drift region LD3 may be equal to or different from the dopant concentration in the drift region LD11 according to some design considerations. In addition, a bottom (such as a bottom surface BS3) of the drift region LD3 may be lower than a bottom (such as a bottom surface BS2) of the drift region LD12 and a bottom (such as a bottom surface BS1) of the drift region LD11 in the vertical direction D3, and in the horizontal direction D1, a length L5 of the drift region LD3 disposed under the gate structure GS1 and the gate oxide layer 30 in the vertical direction D3 may be greater than the length L3 of the drift region LD11 disposed under the gate structure GS1 and the gate oxide layer 30 in the vertical direction D3. It is worth noting that the drift region LD3 in this embodiment may also be applied to other embodiments of the present invention according to some design considerations.

Please refer to FIG. 7, FIG. 7 is a schematic diagram of a high-voltage transistor 105 according to a fifth embodiment of the present invention. As shown in FIG. 7, the high-voltage transistor 105 may further include a silicide layer SA1 and a silicide layer SA2 disposed on the doped region DR11 and the doped region DR12 respectively. In the horizontal direction D1, the silicide layer SA1 is adjacent to or in contact with the salicide block SAB, and the silicide layer SA2 is adjacent to or in contact with the spacer SP2. In addition, the silicide layer SA1 and the silicide layer SA2 may include metal silicide, such as cobalt-silicide, nickel-silicide, or other suitable metal silicide materials. It is worth noting that the silicide layers in this embodiment may also be applied to other embodiments of the present invention according to some design considerations.

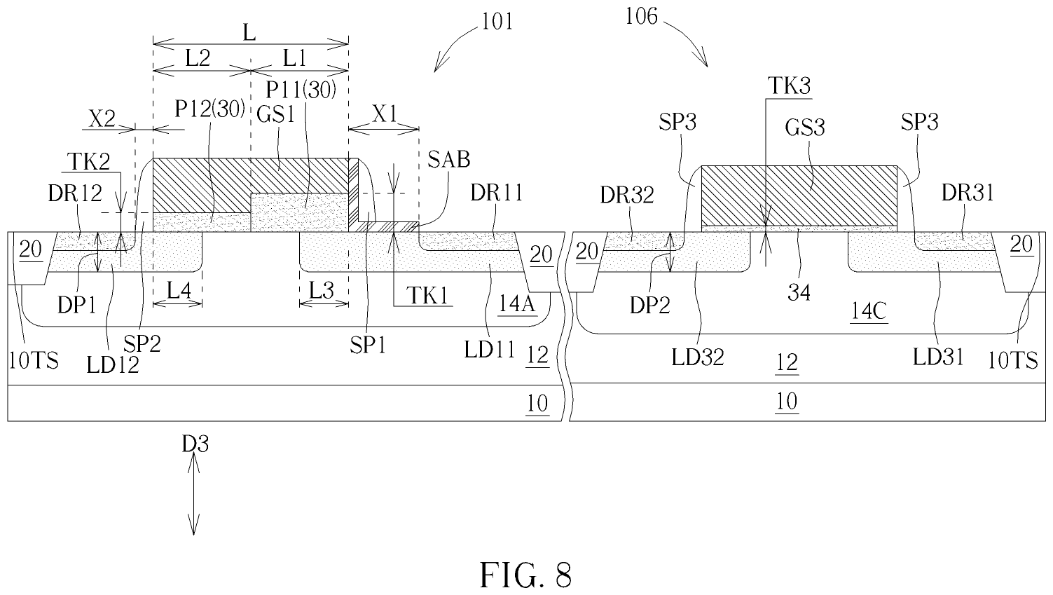

Please refer to FIG. 8, FIG. 8 is a schematic drawing illustrating a semiconductor device according to an embodiment of the present invention. As shown in FIG. 8, the semiconductor device may include a first transistor (such as transistor 101) and a second transistor (such as transistor 106). The transistor 101 includes a structure similar to that of the high-voltage transistor 101 described in the first embodiment (as shown in FIG. 2), and will not be described in detail here. The transistor 106 may include a second well region (such as a well region 14C), a second gate structure (such as a gate structure GS3), and a second gate oxide layer (such as a gate oxide layer 34). The gate structure GS3 is disposed above the well region 14C. The gate oxide layer 34 is disposed between the gate structure GS3 and the well region 14C in the vertical direction D3, the gate oxide layer 34 has a third thickness (such as a thickness TK3), and the thickness TK2 is greater than the thickness TK3.

Additionally, in some embodiments, the transistor 110 may further include a lightly doped region LD31, a lightly doped region LD32, a doped region DR31, a doped region DR32, and as spacer structure SP3. The lightly doped region LD31 and the lightly doped region LD32 are disposed in the well region 14C and located at two opposite sides of the gate structure GS3, respectively, the doped region DR31 and the doped region DR32 are disposed in the lightly doped region LD31 and the lightly doped region LD32, respectively, and the spacer structure SP3 is disposed on the sidewall of the gate structure GS3. In some embodiments, the spacer structure SP3 may overlap a part of the doped region DR31 and a part of the doped region DR32 in the vertical direction D3 or may not overlap the doped region DR31 and the doped region DR32 in the vertical direction D3 according to some design considerations. In some embodiments, a conductivity type of the lightly doped region LD31, a conductivity type of the lightly doped region LD32, a conductivity type of the doped region DR31, and a conductivity type of the doped region DR32 may be identical to one another, a dopant concentration in the doped region DR31 and the doped region DR32 may be higher than that in the lightly doped region LD31 and the lightly doped region LD32, and a conductivity type of the well region 14C may be complementary to the conductivity type of the lightly doped region LD31, the lightly doped region LD32, the doped region DR31, and the doped region DR32. In addition, a depth of the drift region LD11 and/or the drift region LD12 (such as a depth DP1) may be greater than a depth of the lightly doped region LD31 and/or the lightly doped region LD32 (such as a depth DP2), but not limited thereto. The above-mentioned depth of a specific region may be defined as a distance between the bottommost portion of this region in the vertical direction D3 and the top surface 10TS of the semiconductor substrate 10 in the vertical direction D3.

In this embodiment, a medium-high or high-voltage transistor and a low-voltage transistor can be simultaneously formed in different areas on the same substrate 10 to meet different requirements of the semiconductor structure. For example, in some embodiments, the transistor 101 may be a medium-voltage (MV) transistor or a high-voltage transistor, and the transistor 106 may be a low-voltage transistor, but not limited thereto. In addition, the transistor 101 illustrated in FIG. 8 may also be replaced with the high-voltage transistor in other embodiments of the present invention (such as the high-voltage transistors in FIGS. 1-2 and 4-7 described above, but not limited thereto). In other words, in some embodiments, the semiconductor device may include the transistor 106 and at least one of the high-voltage transistors in FIGS. 1-2 and 4-7 described above and/or a high-voltage transistor in other embodiment of the present invention.

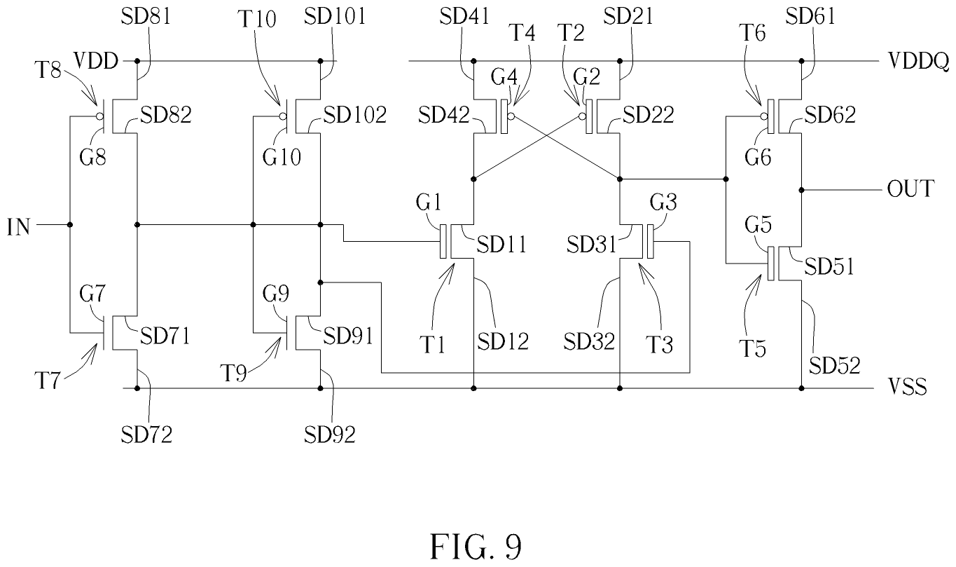

Please refer to FIG. 9 and FIG. 1. FIG. 9 is a schematic equivalent circuit diagram of a level-up shifting circuit according to an embodiment of the present invention. As shown in FIG. 9, the level-up shifting circuit in this embodiment may include a transistor T1, a transistor T2, a transistor T3, a transistor T4, a transistor T5, a transistor T6, a transistor T7, a transistor T8, a transistor T9, and a transistor T10. In some embodiments, the transistor T1, the transistor T3, the transistor T5, the transistor T7, and the transistor T9 may be n-type transistors, and the transistor T2, the transistor T4, the transistor T6, the transistor T8, and the transistor T10 may be p-type transistors. In addition, the transistor T1, the transistor T3, and the transistor T5 may be n-type high-voltage transistors, and the transistor T2, the transistor T4, and the transistor T6 may be p-type high-voltage transistors. A gate electrode G7 of the transistor T7 and a gate electrode G8 of the transistor T8 may be electrically connected to a first terminal IN, a source/drain electrode SD81 of the transistor T8 and a source/drain electrode SD101 of the transistor T10 may be electrically connected to device voltage VDD, and a source/drain electrode SD12 of the transistor T1, a source/drain electrode SD32 of the transistor T3, a source/drain electrode SD52 of the transistor T5, a source/drain electrode SD72 of the transistor T7, and a source/drain electrode SD92 of the transistor T9 may be electrically connected to reference voltage VSS. A source/drain electrode SD71 of the transistor T7, a source/drain electrode SD82 of the transistor T8, a gate electrode G9 and a source/drain electrode SD91 of the transistor T9, a gate electrode G10 and a source/drain electrode SD102 of the transistor T10, a gate electrode G1 of the transistor T1, and a gate electrode G3 of the transistor T3 may be electrically connected with one another. A gate electrode G2 of the transistor T2, a source/drain electrode SD11 of the transistor T1, and a source/drain electrode SD42 may be electrically connected with one another. A source/drain electrode SD22 of the transistor T2, a source/drain electrode SD31 of the transistor T3, a gate electrode G4 of the transistor T4, a gate electrode G5 of the transistor T5, and a gate electrode G6 of the transistor T6 may be electrically connected to one another. A source/drain electrode SD21 of the transistor T2, a source/drain electrode SD41 of the transistor T4, and a source/drain electrode SD61 of the transistor T6 may be electrically connected to device voltage VDDQ. A source/drain electrode SD51 of the transistor T5 and a source/drain electrode SD62 of the transistor T6 may be electrically connected to a second terminal OUT. In some embodiments, the electric potential of the device voltage VDDQ is higher than the electric potential of the device voltage VDD, and The electric potential of the signal input from the first terminal IN may be raised and output from the second terminal OUT by the level-up shifting circuit in this embodiment.

As mentioned above, the high-voltage transistor of each embodiment of the present invention can be made into an n-type high-voltage transistor or a p-type high-voltage transistor depending on the kind of doped ions. When the high-voltage transistor is an n-type high-voltage transistor, it can be used to replace the transistor T1, the transistor T3 and the transistor T5 in the level-up shifting circuit in FIG. 9, and when the high-voltage transistor is a p-type high-voltage transistor, it can be used to replace the transistor T2, the transistor T4 and the transistor T6 in the level-up shifting circuit in FIG. 9. As for the transistors T7, T8, T9 and T10 in the level-up shifting circuit, they are low-voltage transistors, and their structures may be the same as or similar to those of the transistor 106 in FIG. 8, but they are not limited to this.

As shown in FIG. 9 and FIG. 1, in some embodiments, the high-voltage transistor according to the present invention is applied to a level-up shifting circuit. The relatively thin second portion P12 of the gate oxide layer 30 may be used to lower the threshold voltage of the high-voltage transistor 101, the thickness ratio relationship between the first portion P11 and the second portion P12 of the gate oxide layer 30 may be controlled for avoiding the second portion P12 being too thin, and high voltage may still be applied to the gate structure GS1 for high-voltage operation accordingly. In other words, the high-voltage transistors 101 may be used as some of the transistors T3 in the level-up shifting circuit for improving the condition that the transistors cannot be driven when the device voltage VDD drops, and the operation performance of the level-up shifting circuit may be improved accordingly.

According to the above description and drawings, the present invention provides a transistor, referring to FIGS. 1-2, which includes a well region 14A disposed in a substrate 10, a gate structure GS1 disposed above the well region 14A, and a gate oxide layer 30 located between the gate structure GS1 and the well region 14A, wherein a first portion P11 of the gate oxide layer 30 is thicker than a second portion P12 of the gate oxide layer 30. A first doped region DR11 and a second doped region DR12 are arranged in the well region 14A, wherein the first doped region DR11 and the second doped region DR12 are respectively located at two opposite sides of the gate structure GS1 in a horizontal direction D1. The distance X1 between the first doped region DR11 and the first portion P11 of the gate oxide layer 30 is greater than the distance X2 between the second doped region DR12 and the second portion P12 of the gate oxide layer 30, and the conductivity type of the first doped region DR11 is the same as that of the second doped region DR12. A salicide block SAB located on the substrate 10 and on one side of the gate structure GS1, wherein the salicide block SAB is located between the first portion P11 of the gate oxide layer 30 and the first doped region DR11.

In some embodiments of the present invention, the salicide block SAB is adjacent to the first doped region DR11 in the horizontal direction D1, and the salicide block SAB does not overlap the first doped region DR11 in a vertical direction D3.

In some embodiments of the present invention, the salicide block SAB is not located between the second portion P12 of the gate oxide layer 30 and the second doped region DR12.

In some embodiments of the present invention, it further includes a deep well region 12 disposed in the substrate 10 and below the well region 14A, wherein the conductivity type of the deep well region 12 is complementary to that of the well region 14A, and the conductivity type of the deep well region 12 is the same as that of the first doped region DR11 and the second doped region DR12 (for example, both are n-type).

In some embodiments of the present invention, it also includes a deep well region 12, which is disposed in the substrate 10 and below the well region 14A, wherein the conductivity type of the deep well region 12 is the same as that of the well region 14A, and the conductivity type of the deep well region 12 is complementary to that of the first doped region DR11 and the second doped region DR12 (for example, in some embodiments, the deep well region 12 is n-type, while the first doped region DR11 and the second doped region DR12 are p-type).

In some embodiments of the present invention, it further comprises a first drift region LD11 and a second drift region LD12, which are located in the well region 14A and on both sides of the gate structure GS1, wherein the first doped region DR11 is located in the first drift region LD11 and the second doped region DR12 is located in the second drift region LD12, and the conductivity types of the first and second doped regions DR11 and DR12 are the same as those of the first drift region LD11 and the first drift region.

In some embodiments of the present invention, a third drift region LD3 is further included, which is arranged in the well region 14A and below the first drift region LD11, wherein the bottom BS3 of the third drift region LD3 is lower than the bottom BS2 of the second drift region LD12 (as in the embodiment shown in FIG. 6).

In some embodiments of the present invention, a first spacer SP1 and a second spacer SP2 are respectively located at two sides of the gate structure GS1, wherein the first spacer SP1 is located on the salicide block SAB, the first doped region DR11 is adjacent to the salicide block SAB, and the second doped region DR12 is adjacent to the second spacer SP2.

In some embodiments of the present invention, the length L1 of the first portion P11 of the gate oxide layer 30 in the horizontal direction D1 is different from the length L2 of the second portion P12 of the gate oxide layer 30 in the horizontal direction D1 (as in the embodiment shown in FIG. 4).

The invention also provides a method for manufacturing a transistor, which comprises providing a substrate 10, forming a well region 14A in the substrate 10, and forming a gate oxide layer 30 and a gate structure GS1 on the well region 14A, wherein the gate oxide layer 30 is located between the gate structure GS1 and the well region 14A, and a first portion P11 of the gate oxide layer 30 is thicker than a second portion P12 of the gate oxide layer 30. A first doped region DR11 and a second doped region DR12 are formed in the well region 14A, wherein the first doped region DR11 and the second doped region DR12 are respectively located at two opposite sides of the gate structure GS1 in a horizontal direction D1. The distance X1 between the first doped region DR11 and the first portion P11 of the gate oxide layer 30 is greater than the distance X2 between the second doped region DR12 and the second portion P12 of the gate oxide layer 30, and the conductivity type of the first doped region DR11 is the same as that of the second doped region DR12. A salicide block SAB is formed on the semiconductor substrate 10 and on one side of the gate structure GS1, wherein the salicide block SAB is located between the first portion P11 of the gate oxide layer 30 and the first doped region DR11.

In some embodiments of the present invention, the step of forming the first doped region DR11, the second doped region DR12 and the salicide block SAB further includes forming a salicide block material layer covering a top surface of the gate structure GS1, a sidewall of the gate structure GS1 and part of the surface of the substrate 10 (as shown in FIG. 1), and performing a doping step to form the first doped region DR11 and the second doped region in the well region 14A of the substrate 10, wherein the first doped region DR11 is adjacent to the salicide block material layer on the substrate 10.

In some embodiments of the present invention, it further includes removing pars of the salicide block material layer on the top surface of the gate structure GS1, wherein the remaining salicide block material layer on the substrate 10 is defined as the salicide block SAB, and performing a metal gate replacement step to replace the gate structure GS1 with a metal gate (as shown in FIG. 2).

In some embodiments of the present invention, the salicide block SAB is adjacent to the first doped region DR11 in the horizontal direction D1, and the salicide block SAB does not overlap the first doped region DR11 in a vertical direction.

In some embodiments of the present invention, the salicide block SAB is not located between the second portion P12 of the gate oxide layer and the second doped region DR12.

In some embodiments of the present invention, it further includes forming a deep well region 12, which is disposed in the substrate 10 and below the well region 14A, wherein the conductivity type of the deep well region 12 is complementary to that of the well region 14A, and the conductivity type of the deep well region 12 is the same as that of the first doped region DR11 and the second doped region DR12 (for example, both are n-type).

In some embodiments of the present invention, it also includes forming a deep well region 12, which is arranged in the substrate 10 and below the well region 14A, wherein the conductivity type of the deep well region 12 is the same as that of the well region 14A, and the conductivity type of the deep well region 12 is complementary to that of the first doped region DR11 and the second doped region DR12 (for example, in some embodiments, the deep well region 12 is n-type, while the first doped region DR11 and the second doped region DR12 are p-type).

In some embodiments of the present invention, it further includes forming a first drift region LD11 and a second drift region LD12, which are located in the well region 14A and on both sides of the gate structure GS1, wherein the first doped region DR11 is located in the first drift region LD11 and the second doped region DR12 is located in the second drift region LD12, and the conductivity types of the first and second doped regions DR11 and DR12 are the same as those of the first drift region LD11.

In some embodiments of the present invention, it further includes forming a third drift region LD3, which is arranged in the well region 14A and below the first drift region LD11, wherein the bottom BS3 of the third drift region LD3 is lower than the bottom BS2 of the second drift region LD12 (as in the embodiment shown in FIG. 6).

In some embodiments of the present invention, a first spacer SP1 and a second spacer SP2 are formed on both sides of the gate structure GS1, respectively, wherein the first spacer SP1 is located on the salicide block SAB, the first doped region DR11 is adjacent to the salicide block SAB, and the second doped region DR12 is adjacent to the second spacer SP2.

In some embodiments of the present invention, the length L1 of the first portion P11 of the gate oxide layer 30 in the horizontal direction D1 is different from the length L2 of the second portion P12 of the gate oxide layer 30 in the horizontal direction D1 (as in the embodiment shown in FIG. 4).

The invention is characterized by providing a structure of a high-voltage transistor and a manufacturing method thereof. The threshold voltage of high-voltage transistor is reduced by using gate oxide layers with different thickness portions, and the gate structure can still be applied with high voltage by controlling the thickness ratio between different portions of the gate oxide layer to meet the operating requirements of specific circuits. In addition, by forming a salicide block and extending the salicide block to the drain side of the high-voltage transistor, the doped region on the drain side of the high-voltage transistor is far away from the gate structure for a certain distance, so that the stability of the high-voltage transistor can be improved. And because only the doped region on the drain side is far away from the gate structure, the doped region on the source side is still relatively close to the gate structure, the influence on the Vt (threshold voltage) of the whole high-voltage transistor is small. When the high-voltage transistor is used in the level-up shifting circuit, the condition that the high-voltage transistor cannot be driven when the driving voltage drops may be improved, and the operation performance of the level-up shifting circuit may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor comprising:
a well region disposed in a substrate;
a gate structure disposed above the well region;
a gate oxide layer disposed between the gate structure and the well region, wherein a first portion of the gate oxide layer is thicker than a second portion of the gate oxide layer;
a first doped region and a second doped region arranged in the well region, wherein the first doped region and the second doped region are located at two opposite sides of the gate structure in a horizontal direction, wherein the distance between the first doped region and the first portion of the gate oxide layer is greater than the distance between the second doped region and the second portion of the gate oxide layer along the horizontal direction, and a conductivity type of the first doped region is the same as a conductivity type of the second doped region; and
a salicide block located on the substrate and at one side of the gate structure, wherein the salicide block is located between the first portion of the gate oxide layer and the first doped region.

2. The transistor according to claim 1, wherein the salicide block is adjacent to the first doped region in the horizontal direction, and the salicide block does not overlap the first doped region in a vertical direction.

3. The transistor according to claim 1, wherein the salicide block is not located between the second portion of the gate oxide layer and the second doped region.

4. The transistor according to claim 1, further comprising:
a deep well region disposed in the substrate and located under the well region, wherein a conductivity type of the deep well region is complementary to a conductivity type of the well region, and the conductivity type of the deep well region is identical to the conductivity type of the first doped region and the conductivity type of the second doped region.

5. The transistor according to claim 1, further comprising:
a deep well region disposed in the substrate and located under the well region, wherein a conductivity type of the deep well region is identical to a conductivity type of the well region, and the conductivity type of the deep well region is complementary to the conductivity type of the first doped region and the conductivity type of the second doped region.

6. The transistor according to claim 1, further comprising:
a first drift region and a second drift region located in the well region and on both sides of the gate structure, wherein the first doped region is located in the first drift region and the second doped region is located in the second drift region, and the conductivity types of the first doped region and the second doped region are the same as the conductivity types of the first drift region and the second drift region.

7. The transistor according to claim 6, further comprising:
a third drift region disposed in the well region and below the first drift region, wherein a bottom of the third drift region is lower than a bottom of the second drift region.

8. The transistor according to claim 1, further comprising a first spacer and a second spacer located on both sides of the gate structure, wherein the first spacer is located on the salicide block, the first doped region is adjacent to the salicide block, and the second doped region is adjacent to the second spacer.

9. The transistor according to claim 1, wherein a length of the first portion of the gate oxide layer in the horizontal direction is different from a length of the second portion of the gate oxide layer in the horizontal direction.

10. A method for manufacturing a transistor, comprising:
providing a well region disposed in a substrate;
forming a gate structure disposed above the well region;
forming a gate oxide layer disposed between the gate structure and the well region, wherein a first portion of the gate oxide layer is thicker than a second portion of the gate oxide layer;
forming a first doped region and a second doped region arranged in the well region, wherein the first doped region and the second doped region are located at two opposite sides of the gate structure in a horizontal direction, wherein the distance between the first doped region and the first portion of the gate oxide layer is greater than the distance between the second doped region and the second portion of the gate oxide layer along the horizontal direction, and a conductivity type of the first doped region is the same as a conductivity type of the second doped region; and
forming a salicide block located on the substrate and at one side of the gate structure, wherein the salicide block is located between the first portion of the gate oxide layer and the first doped region.

11. The method for manufacturing a transistor according to claim 10, wherein the step of forming the first doped region, the second doped region and the salicide block further comprises:
forming a salicide block material layer covering a top surface of the gate structure, a sidewall of the gate structure, and part of the surface of the substrate;
performing a doping step to form the first doped region and the second doped region in the well region of the substrate, wherein the first doped region is adjacent to the salicide block material layer on the substrate.

12. The method for manufacturing a transistor according to claim 11, further comprising:
removing parts of the salicide block material layer on the top surface of the gate structure, wherein the remaining salicide block material layer on the substrate is defined as the salicide block;
performing a metal gate replacement step to replace the gate structure with a metal gate.

13. The method for manufacturing a transistor according to claim 10, wherein the salicide block is adjacent to the first doped region in the horizontal direction, and the salicide block does not overlap the first doped region in a vertical direction.

14. The method of manufacturing a transistor according to claim 10, wherein the salicide block is not located between the second portion of the gate oxide layer and the second doped region.

15. The method for manufacturing a transistor according to claim 10, further comprising:
forming a deep well region disposed in the substrate and located under the well region, wherein a conductivity type of the deep well region is complementary to a conductivity type of the well region, and the conductivity type of the deep well region is identical to the conductivity type of the first doped region and the conductivity type of the second doped region.

16. The method for manufacturing a transistor according to claim 10, further comprising:
forming a deep well region disposed in the substrate and located under the well region, wherein a conductivity type of the deep well region is identical to a conductivity type of the well region, and the conductivity type of the deep well region is complementary to the conductivity type of the first doped region and the conductivity type of the second doped region.

17. The method for manufacturing a transistor according to claim 10, further comprising:
forming a first drift region and a second drift region located in the well region and on both sides of the gate structure, wherein the first doped region is located in the first drift region and the second doped region is located in the second drift region, and the conductivity types of the first doped region and the second doped region are the same as the conductivity types of the first drift region and the second drift region.

18. The method for manufacturing a transistor according to claim 17, further comprising:
forming a third drift region disposed in the well region and below the first drift region, wherein a bottom of the third drift region is lower than a bottom of the second drift region.

19. The method for manufacturing a transistor according to claim 10, further comprising forming a first spacer and a second spacer located on both sides of the gate structure, wherein the first spacer is located on the salicide block, the first doped region is adjacent to the salicide block, and the second doped region is adjacent to the second spacer.

20. The method for manufacturing a transistor according to claim 10, wherein a length of the first portion of the gate oxide layer in the horizontal direction is different from a length of the second portion of the gate oxide layer in the horizontal direction.
